(19) United States
(12) Patent Application Publication
(10) Pub. No.: US 2026/0029471 A1
(43) Pub. Date: Jan. 29, 2026

(54) Methods for Electrochemical Mechanistic Analysis of Cyclic Voltammograms

(71) Applicant: The Regents of the University of California, Oakland, CA (US)

(72) Inventors: Chong Liu, Oakland, CA (US); Quanguan Gu, Oakland, CA (US); Benjamin Hoar, Oakland, CA (US); Weitong Zhang, Oakland, CA (US)

(73) Assignee: The Regents of the University of California, Oakland, CA (US)

(21) Appl. No.: 18/871,401

(22) PCT Filed: Jun. 6, 2023
(86) PCT No.: PCT/US2023/068008

§ 371 Date: Dec. 3, 2024

Related U.S. Application Data
(60) Provisional application No. 63/365,902, filed on Jun. 6, 2022.

(51) Int. Cl. G01R 31/367; G01N 27/48

(52) U.S. Cl. CPC G01R 31/367; G01N 27/48

(57) ABSTRACT

Systems and methods for automatic analysis of underlying electrochemical mechanisms of various electrochemistry systems are described. The automatic analysis can reduce manual analysis performed by humans to a minimum. Electrochemical mechanisms of electrochemical systems measured by cyclic voltammograms can be characterized, categorized and ranked. The deep learning-based processes can provide qualitative, semi-quantitative, and/or quantitative results to deconvolute complex electrochemical systems.

### CROSS-REFERENCE TO RELATED APPLICATIONS

The current application is a national stage of PCT Patent Application No. PCT/US2023/068008, entitled “Methods for Electrochemical Mechanistic Analysis of Cyclic Voltammograms” to Chong Liu et al., filed Jun. 6, 2022, which claims the benefit of priority to U.S. Provisional Patent Application No. 63/365,902 entitled “Electrochemical Mechanistic Analysis from Cyclic Voltammograms Based on Deep Learning” filed Jun. 6, 2022. The disclosures of which are hereby incorporated by reference in its entirety for all purposes.

### STATEMENT OF FEDERALLY SPONSORED RESEARCH

This invention was made with government support under Grant Number 2140762, awarded by the National Science Foundation and under Grant Number GM138241, awarded by the National Institutes of Health. The government has certain rights in the invention.

### FIELD OF INVENTION

The present disclosure generally relates to methods for analyzing cyclic voltammograms; and more particularly to electrochemical mechanistic analysis of cyclic voltammograms using deep learning.

### BACKGROUND

Cyclic voltammetry is a common electrochemical characterization technique that can generate valuable mechanistic information for redox-active chemical systems. Cyclic voltammetry has been widely applied to electrochemical applications in sensing, energy-storage, chemical transformations. However, the general protocol of initial mechanistic analysis after experiments has remained largely unchanged since its inception. Researchers manually inspect the shapes and variations of cyclic voltammograms under multiple different scan rates (v), sometimes with different reactant concentrations, and subsequently hypothesize a qualitative mechanism including interfacial charge transfers (E step) and/or solution reactions (C steps). Additional experiments and/or numerical simulations may be applied if extracting quantitative kinetic information is needed. Such manual inspection may require extensive research training, potentially incurs human bias, and may not be compatible with automated testing needed for high-throughput screenings.

### BRIEF SUMMARY

Methods and systems for electrochemical mechanistic analysis of cyclic voltammograms using deep learning are described.

One embodiment of the invention includes a method of analyzing an electrochemistry system comprising,
obtaining at least one cyclic voltammogram from an electrochemistry system;
generating a dataset from the at least one cyclic voltammogram;
evaluating the dataset using a machine learning model in a virtual space; and
   when the evaluated dataset satisfies at least one criterion by the machine learning model, determining a probability of at least one electrochemical mechanism of the electrochemistry system.

In another embodiment, the dataset comprises numerical values of current, current density, scan rate, and any combinations thereof.

In a further embodiment, the electrochemical mechanism is selected from the group consisting of a charge transfer, an interfacial charge transfer, an electron transfer, a chemical reaction, a solution reaction, a diffusion reaction, a single reversible electron transfers (Eᵣ), a Eᵣ step followed by reversible C steps (EᵣCᵣ), a Eᵣ step preceded by Cᵣ step (CᵣEᵣ), a systems of two Eᵣ steps connected by an irreversible rate-limiting C step with the second Eᵣ step being more thermodynamically facile than the first one (ECE), a two-electron transfer wherein the second Eᵣ step is replaced by a solution disproportionation reaction (DISP1), and any combinations thereof.

In a further embodiment, at least one probability of an electrochemical mechanism of the electrochemistry system is determined to at least 95% accuracy.

Another further embodiment comprises determining a plurality of electrochemical mechanisms and ranking the plurality of electrochemical mechanisms of the electrochemistry system.

Another yet embodiment further comprises determining stoichiometric homogenous electrochemical mechanisms selected from the group consisting of: Eᵣ, EᵣCᵣ, CᵣEᵣ, ECE, and DISP1.

In a yet another embodiment, the electrochemistry system is a portion of a system selected from the group consisting of: a catalyst, a fuel cell, a battery, a redox flow battery.

In an additional embodiment, the catalyst catalyzes a process selected from the group consisting of: a carbon dioxide reduction process, a carbon fixation process, a carbon sequestration process, a water electrolysis process, a hydrogen production process, and an energy storage process.

Another embodiment includes a method of training a machine model for analyzing an electrochemistry system comprising,
generating at least one dataset for at least one electrochemical mechanism comprising a set of parameters based on a definition of the at least one electrochemical mechanism; and
providing the at least one dataset as input training data to a machine learning model and training the machine learning model using the at least one dataset.

In a further embodiment again, the at least one dataset is generated via simulation.

Another further embodiment comprises adding Gaussian-type noise to the at least one dataset.

In a further embodiment again, the at least one dataset comprises numerical values of current, current density, scan rate, and any combinations thereof.

In another further yet embodiment, the electrochemical mechanism is selected from the group consisting of a charge transfer, an interfacial charge transfer, an electron transfer, a chemical reaction, a solution reaction, a diffusion reaction, a single reversible electron transfers (Eᵣ), a Eᵣ step followed by reversible C steps (EᵣCᵣ), a Eᵣ step preceded by Cᵣ step (CᵣEᵣ), a systems of two Eᵣ steps connected by an irreversible rate-limiting C step with the second Eᵣ step being more thermodynamically facile than the first one (ECE), a two-electron transfer wherein the second Eᵣ step is replaced by a solution disproportionation reaction (DISP1), and any combinations thereof.

In yet another embodiment, the set of parameters is selected from the group consisting of: numbers of scan rate, values of scan rate, electrode double layer capacitance, standard rate constant of interfacial charge transfer in a concentration-dependent Butler-Volmer equation following Nicholson's formalism in the Eᵣ step, equilibrium constants and forward/backward rate constants in the Cᵣ step based on Savéant's definitions, and any combinations thereof.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1A illustrates a process of identifying electrochemical mechanisms in accordance with an embodiment.

FIG. 1B illustrates a block diagram of a computing device for identifying electrochemical mechanism in accordance with an embodiment.

FIG. 1C illustrates a block diagram of an electrochemical mechanism identification device in accordance with an embodiment.

FIG. 2 illustrates a process of training a machine learning model for identifying electrochemical mechanisms in accordance with an embodiment.

FIG. 3A illustrates DL based automatic inspection of electrochemistry mechanisms in accordance with an embodiment.

FIG. 3B illustrates cyclic voltammograms of various electrochemical mechanisms in accordance with an embodiment.

FIG. 4 illustrates a structure of input data, convolutional neural network architecture, and output of electrochemical mechanisms in accordance with an embodiment.

FIGS. 5A-5F illustrate simulated cyclic voltammograms with different levels of Gaussian noises in accordance with an embodiment.

FIG. 6A illustrates confusion matrix of DL model trained by simulated cyclic voltammograms with explicit values of scan rate (v) as input data in accordance with an embodiment.

FIG. 6B illustrates confusion matrix trained without explicit values of scan rate (v) as input data in accordance with an embodiment.

FIG. 6C illustrates the accuracies of the DL model when tested with simulated voltammograms with varying values of n and σ in accordance with an embodiment.

FIGS. 7A-7H illustrate training of machine learning algorithms for cyclic voltammetry in accordance with an embodiment.

FIGS. 8A-8I illustrate DL model predicting electrochemical mechanisms in various experimental scenarios in accordance with an embodiment.

FIGS. 9A-9E illustrate the “importance” plots of simulated cyclic voltammograms in accordance with an embodiment.

FIGS. 10A-10G illustrate semi-qualitative analysis of cyclic voltammograms with DL algorithm in accordance with an embodiment.

### DETAILED DESCRIPTION

Systems and methods described herein enable automatic analysis of underlying electrochemical mechanisms from cyclic voltammograms using deep learning-based processes. The automatic analysis can reduce manual analysis performed by humans to a minimum. In several embodiments, electrochemical mechanisms of the electrochemical processes measured by cyclic voltammograms can be characterized, categorized and ranked. In a number of embodiments, probabilities for various electrochemical mechanisms can be generated as the analysis results. The automated analysis in accordance with some embodiments can be applied to simulated and/or experimental scenarios and achieve an accuracy of at least 95%. In many embodiments, deep learning-based analysis of cyclic voltammograms can analyze regions of cyclic voltammogram curves that may be seldomly examined by manual analysis, and can unveil potential new features in the voltammograms elusive to manual inspection. The deep learning-based processes can provide qualitative, semi-quantitative, and/or quantitative results to deconvolute complex electrochemical systems.

Many embodiments perform automatic electrochemical analysis based on deep learning that can be used to analyze homogenous and/or heterogeneous electrochemical mechanisms, stoichiometric and/or catalytic transformations. Automated and accurate analysis of electrochemical processes using deep learning-based models can be applied to various industries including (but not limited to) catalysts, batteries, fuel cells, and/or electric vehicles. Automatic analysis can have advantages of analyzing complex reaction schemes that may be beyond the capacity of manual analysis, such as square diagrams with the possibility of concerted pathways in proton-coupled electron transfer systems. Quick turnover of the electrochemical mechanism analysis results can be used for high throughput screening of catalyst candidates. Being able to accurately characterize the electrochemical mechanisms of the reactions can be useful in identifying competing pathways of complex electrochemical processes, discovering catalyst degradation and/or catalyst turnover. Catalysts can be used in various processes including (but not limited to) carbon dioxide reduction, carbon fixation, carbon sequestration, water electrolysis, hydrogen production, and energy storage. Catalysts can also be applied in redox flow batteries. The model can be applicable to analyze complex electrochemical systems when competing mechanisms are intertwined together. Being more sensitive and capable of detecting subtle elusive features, the electrochemical analysis in accordance with several embodiments may semi-quantitatively analyze competing pathways and observe the gradual transition from one mechanism to another. The semi-quantitative output of the inspection methods in accordance with some embodiments also offer mathematically quantified features, which can be the subject of various sequential design strategies including (but not limited to) Bayesian optimization that seeks to maximize electrochemical transformations with optimal experimental conditions.

While cyclic voltammograms are typically presented as images, much of the white space in voltammograms contains little information. Previous work on electrochemistry analysis with deep neural networks has used graphs of cyclic voltammograms as inputs, and had a prediction accuracy of less than about 90%. The deep learning-based analysis processes in accordance with many embodiments use datasets including (but not limited to) current and scan rate as inputs, instead of images of cyclic voltammograms, and can achieve a higher accuracy of determining electrochemical mechanisms. In a number of embodiments, electrochemical mechanisms including (but not limited to) charge transfers, interfacial charge transfers, electron transfers, chemical reactions, solution reactions, diffusion reactions, single reversible electron transfers (Eᵣ), Eᵣ step followed by reversible C steps (EᵣCᵣ), Eᵣ step preceded by Cᵣ step (CᵣEᵣ), systems of two Eᵣ steps connected by an irreversible rate-limiting C step with the second Eᵣ step being more thermodynamically facile than the first one (ECE), two-electron transfer that is similar to ECE yet the second Eᵣ step is replaced by a solution disproportionation reaction (DISP1), and any combinations thereof can be characterized and ranked using the automatic analysis. Many embodiments provide deep learning-based processes using (but not limited to) residual neural networks (ResNet) to analyze cyclic voltammograms. In a number of embodiments, the model can generate qualitative and quantitative characterization of electrochemical mechanisms associated with the reactions as output. The neural network can yield a vector with each component representing the probability or fraction towards various electrochemical mechanisms. The classification process can be completed by designating the electrochemical mechanisms of the largest component in a vector as the most probable or most prominent one for the studied electrochemical system. Non-zero probabilities/fractions for mechanisms other than the most probable/prominent one may suggest either a competing reaction or a gradual transition from one mechanism to another. Certain embodiments provide semi-quantitative observations of the gradual transitions of electrochemical mechanisms.

Several embodiments provide synthetic datasets for training of the deep learning models. Synthetic training datasets can cover various electrochemical scenarios with better uniformity in data quality and higher accuracy. Cyclic voltammograms based on the targeted mechanisms can be numerically simulated as the training sets for deep neural networks. A training dataset can be generated for each electrochemical mechanism. Numerical conditions including (but not limited to) numerical models of partial differential equations (PDEs), boundary conditions, and initial conditions can be constructed based on the definitions of various mechanisms. Parameters of the numerical models including (but not limited to), the numbers and values of scan rate, electrodes' double layer capacitance, standard rate constant of interfacial charge transfer in the concentration-dependent Butler-Volmer equation following Nicholson's formalism in the Eᵣ step, and the equilibrium constants and forward/backward rate constants in the Cᵣ step based on Savéant's definitions, can be incorporated into the simulations and carefully constrained with practical and fundamental considerations. Some embodiments include Gaussian-type noise due to background and instrumentation in the experimental voltammograms. Gaussian noise of varying degrees of standard deviation relative to the maximal current densities can be added to the simulated voltammograms to better reflect the realistic electrochemical data but also increases the algorithm's tolerance towards noises in automatic mechanism categorization.

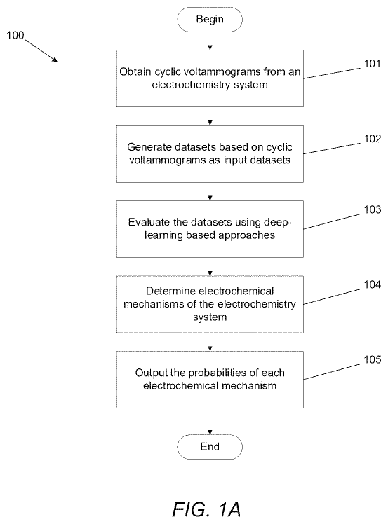

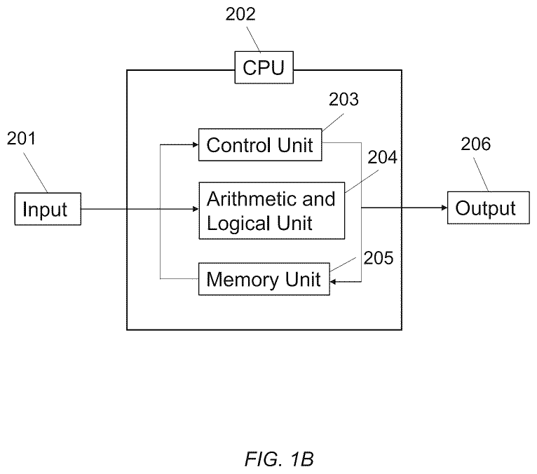

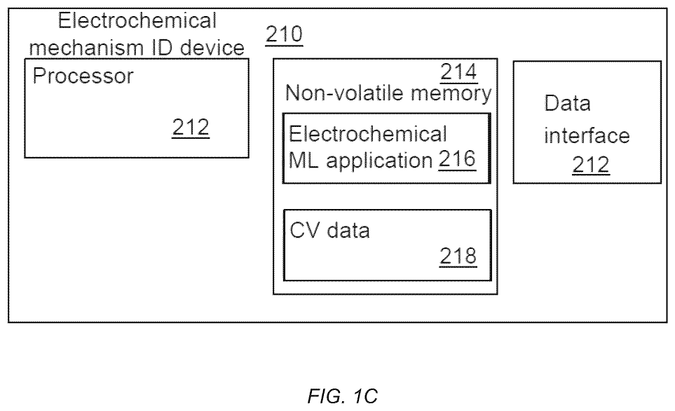

FIG. 1A illustrates a process for identifying electrochemical mechanism in accordance with an embodiment of the invention. The process 100 starts by obtaining (101) cyclic voltammograms from one or more electrochemistry systems. Cyclic voltammetry can analyze electrochemical properties of a range of electrochemical systems such as (but not limited to) redox reaction systems, batteries, fuel cells, and electrolysis systems. In cyclic voltammetry, forwards and backwards potential sweep produces a plot known as a cyclic voltammogram. In cyclic voltammetry, the electrode potential ramps linearly versus time in cyclical phases. The rate of voltage change over time during each of these phases is known as the scan rate (V/s). The potential is measured between the working electrode and the reference electrode, while the current is measured between the working electrode and the counter electrode. Current (i) can be plotted versus applied potential (E) in the voltammograms. Cyclic voltammograms can be generated experimentally and/or via simulation. Cyclic voltammograms can have different scan rates and different current readouts.

One or more datasets can be generated (102) based on cyclic voltammograms as input datasets. Input datasets from cyclic voltammograms can include (but are not limited to) current, current density, and/or scan rate, as will be discussed with respect to various embodiments further below. Many embodiments implement two-dimensional matrixes employed to store electrochemical information for the analysis. Additionally, data cleaning and/or normalization can be used to reduce and/or remove noise in the cyclic voltammograms before deriving datasets as will be discussed in greater detail further below.

The process evaluates (103) the one or more datasets using a machine learning model in a virtual space. Many embodiments implement deep learning-based processes using (but not limited to) residual neural networks (ResNet) to analyze cyclic voltammograms. The model can generate qualitative and quantitative characterization of electrochemical mechanisms associated with the reactions.

The process determines (104) a probability of at least one electrochemical mechanism of the electrochemistry system, when the evaluated dataset satisfies at least one criterion by the machine learning model. Examples of electrochemical mechanisms that can be determined by the method include (but are not limited to) charge transfers, interfacial charge transfers, electron transfers, chemical reactions, solution reactions, diffusion reactions, single reversible electron transfers (Eᵣ), Eᵣ step followed by reversible C steps (EᵣCᵣ), Eᵣ step preceded by Cᵣ step (CᵣEᵣ), systems of two Eᵣ steps connected by an irreversible rate-limiting C step with the second Eᵣ step being more thermodynamically facile than the first one (ECE), two-electron transfer that is similar to ECE yet the second Eᵣ step is replaced by a solution disproportionation reaction (DISP1), and any combinations thereof. Various electrochemical mechanisms can be characterized and/or ranked via automatic analysis. The neural network can yield a vector with each component representing the probability and/or fraction towards various electrochemical mechanisms. The classification process can be completed by designating the electrochemical mechanisms of the largest component in a vector as the most probable and/or most prominent one for the electrochemical system. Non-zero probabilities and/or fractions for mechanisms other than the most probable/prominent one may suggest either a competing reaction or a gradual transition from one mechanism to another. The process outputs (105) the probabilities of each identified electrochemical mechanism associated with the cyclic voltammograms.

FIG. 1B illustrates a block diagram of a computing device for identifying electrochemical mechanisms in accordance with an embodiment. Input data such as dataset derived from CV scans can be provided to the computing device through an input unit 201. The input unit 201 can provide the data from a user to the computing device. Input units can include devices such as (but not limited to) a mouse, a keyboard, a pen, a scanner, a removeable memory interface, and/or a network interface. The computing device may accept the data in binary form. It can process the data by transmitting the converted data into a main memory of the computing device.

Central Processing Unit or the CPU 202 conducts arithmetical and logical operations in the computing device. CPU 202 may comprise two units, ALU (Arithmetic Logic Unit) 204 and CU (Control Unit) 203. ALU and CU may work in sync.

ALU 204 may be made of two terms, arithmetic and logic. Data can be inserted through the input unit into the primary memory. ALU 204 can perform arithmetical operations such as, but not limited to, addition, subtraction, multiplication, and division on data. ALU can perform calculations on the data and then send back data to the storage. ALU can also perform logical operations such as AND, OR, Equal to, Less than. ALU can also conduct merging, sorting, and selection of the given data.

The control unit 203 is the controller of activities/tasks and operations performed inside the computing device. The memory unit 205 can send a set of instructions to the control unit 203. Then the control unit in turn can convert those instructions. These instructions can be converted to control signals. These control signals help in prioritizing and scheduling activities. Thus, the control unit coordinates the tasks inside the computer in sync with the input and output units.

Data to be processed or that has been processed can be stored in the memory unit 205. It can transmit it to other parts of the computer when requested. The memory unit can work in sync with the CPU.

The output information on predicted electrochemical mechanism probabilities can be provided to a user through the output unit 206. Output units can include, but are not limited to, printers, monitors, projectors, removeable memory interfaces, and/or network interfaces. The output unit 206 can provide the data either in the form of a soft copy or a hard copy. The output unit can accept the data in binary form from the computing device and convert it into a readable form for a user.

Another view of electrochemical mechanism identification device in accordance with many embodiments of the invention is illustrated in FIG. 1C. The electrochemical mechanism identification device 210 includes a processor 212, non-volatile memory 214, and a data interface 212. In the illustrated embodiment, non-volatile memory 214 can include an electrochemical machine learning application 216 and cyclic voltammograms data 218. The electrochemical machine learning application 216 can be machine-readable instructions that can configure the processor 212 to execute the instructions, thereby creating machine learning models using cyclic voltammograms data such as according to processes discussed further below. In several embodiments, cyclic voltammograms data and/or output data from the electrochemical ML application 216 can be input and/or output by data interface 212. Data interface 212 can be any of a variety of interfaces, such as, but not limited to, removeable memory or a network interface.

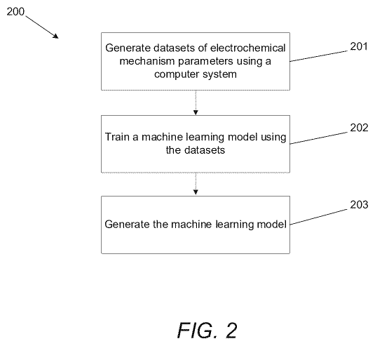

FIG. 2 illustrates a process for training the neural networks for identifying electrochemical mechanisms in accordance with an embodiment. The training process 200 starts by generating (201) a plurality of datasets of electrochemical mechanism parameters using a computer system. Examples of electrochemical mechanism parameters can include (but are not limited to) current, current density, and/or scan rate. Parameters can be collected from a plurality of experimental measurements and/or from simulated datasets. Gaussian-type noise can be added to the training dataset to mimic various reaction conditions. Synthetic training datasets can cover various electrochemical scenarios with higher uniformity in data quality and accuracy. Cyclic voltammograms based on the targeted mechanisms can be numerically simulated as the training sets for deep neural networks.

The process trains (202) a machine learning model with the plurality of datasets. Deep learning-based processes such as (but not limited to) residual neural networks (ResNet) can be implemented as the machine learning model. A training dataset can be generated for each electrochemical mechanism. Numerical conditions including (but not limited to) numerical models of partial differential equations (PDEs), boundary conditions, and initial conditions can be constructed based on the definitions of various mechanisms. Parameters of the numerical models including (but not limited to) numbers and values of scan rate, electrode double layer capacitance, standard rate constant of interfacial charge transfer in the concentration-dependent Butler-Volmer equation following Nicholson's formalism in the Eᵣ step, and the equilibrium constants and forward/backward rate constants in the Cᵣ step based on Savéant's definitions, can be incorporated into the simulations and constrained with practical and fundamental considerations. Gaussian noise of varying degrees of standard deviation relative to the maximal current densities can be added to the simulated voltammograms to better reflect the realistic electrochemical data but also increases the algorithm's tolerance towards noises in automatic mechanism categorization. The process generates (203) the machine learning model when training criteria are satisfied.

Systems and methods for implementing electrochemical analysis using deep learning-based processes in accordance with various embodiments of the invention are discussed further below.

### Electrochemical Mechanistic Analysis

Machine-learning algorithms such as those of deep-learning (DL) are capable of aiding mechanism categorization in cyclic voltammetry. In electrochemistry, the kinetics of E and/or C steps formulate the set of partial differential equations (PDE) and boundary conditions hence dictate the i-E characteristics recorded in the cyclic voltammograms under a collection of different v values ({v, i(E)}ₙ, n, number of different v values). The mathematically bijective relationship between electrochemical mechanism ({Eᵢ, Cⱼ}) and electrochemically accessible parameter space of the combined voltammograms {v, i(E)}ₙ suggests that it is feasible to employ DL algorithms to designate discrete mechanisms from sufficiently sampled cyclic voltammograms with minimal ambiguity. This bijective relationship enables numerical simulations based on finite-element methods and by artificial neural networks to be used as a tool to efficiently search the parameter space of cyclic voltammograms and fit kinetic parameters upon a mechanism determined a priori by manual inspections of voltammogram. However, electrochemical mechanistic investigations remain trial-and-error because the determination of the aforementioned a priori mechanism before any quantitative studies still relies on manual inspection.

Several embodiments implement a set of cyclic voltammograms simulated from finite-element methods based on pre-set mechanism designations in the first-order approximation for the establishment of a DL model that analyzes cyclic voltammograms and qualitatively categorizes mechanisms provided a large enough sampling of {v, i(E)}ₙ. Many embodiments utilize DL-based analysis and hypothesize that the bijective relationship between {Eᵢ, Cⱼ} and {v, i(E)}ₙ enables the establishment of DL algorithms that detect and utilize subtle voltammogram features, and observe the evolution of “edge” cases when two mechanisms co-exist, and/or one mechanism is transitioning into another one. The voltammogram features are not commonly used as mechanistic discriminants by humans. The established algorithms can be continuously refined and improved from experimental data. The algorithms can be used for analyzing complex mechanistic scenarios and addressing the lack of automatic, high-throughput mechanistic analysis in electrochemistry.

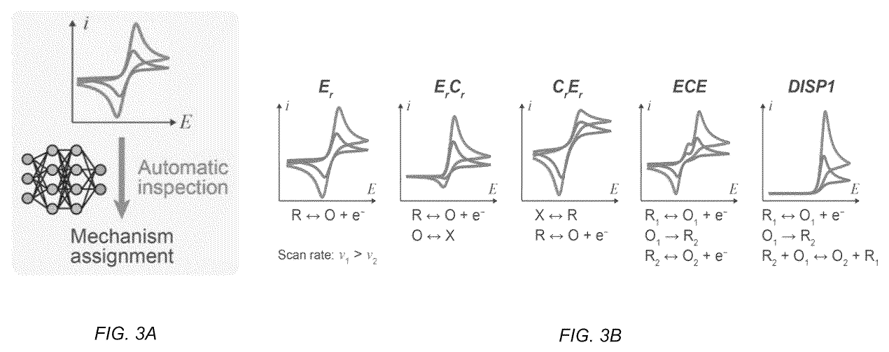

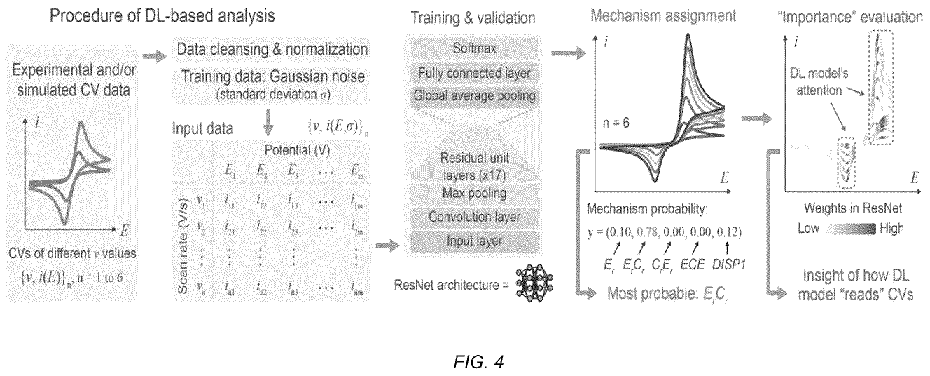

Many embodiments provide a DL algorithm for automatic mechanistic analysis for cyclic voltammetry. DL algorithms using residual neural networks (ResNet) architecture can be established to analyze cyclic voltammograms at different scan rates {v, i(E)} and yield the electrochemical system's probability towards at least five common stoichiometric homogenous mechanisms in electrochemistry. FIG. 3A illustrates DL based automatic inspection of electrochemistry mechanisms in accordance with an embodiment. Advantages of DL based approaches include: high throughput; minimizing human bias; self-improving; and compatible with automation. FIG. 3B illustrates cyclic voltammograms of various electrochemical mechanisms in accordance with an embodiment. Electrochemical mechanisms shown in FIG. 3B include a single reversible electron transfer (Eᵣ), a Eᵣ step followed by a reversible C step (EᵣCᵣ), a Eᵣ step preceded by a Cᵣ step (CᵣEᵣ), a system of two Eᵣ steps connected by an irreversible rate-limiting C step with the second Eᵣ step being more thermodynamically facile than the first one (ECE), and a two-electron transfer that is similar to ECE yet the second Eᵣ step is replaced by a solution disproportionation reaction (DISP1).

In several embodiments, deep-learning based methods can accurately designate mechanisms in simulated and experimental cyclic voltammograms. Characterization of the mechanisms may unveil new features in the voltammograms elusive to manual inspection, as well as semi-quantitatively observing the gradual transitions of electrochemical mechanisms. The methods can be applied to analyze complex electrochemical systems when competing mechanisms are intertwined together. Automatic mechanistic analysis in cyclic voltammetry can be applied in automated high-throughput research to investigate mechanisms in electrochemical systems with minimal human intervention.

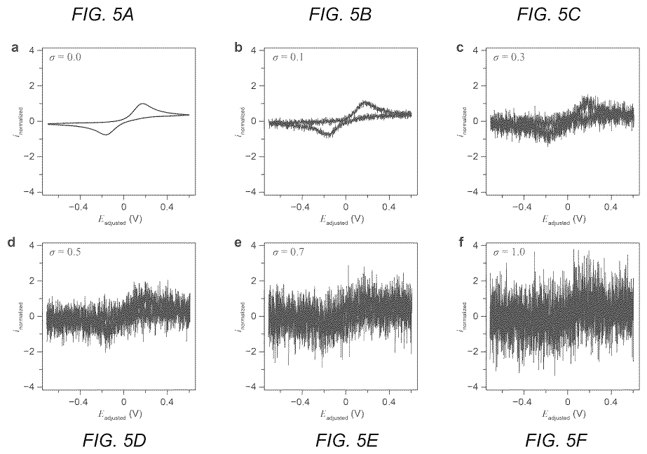

Some embodiments sanitize and transform the data of cyclic voltammograms into two-dimensional matrixes suitable for DL algorithms of ResNet architecture. While cyclic voltammograms are typically presented as images, much of the white space in voltammograms contains little if not nil information. Many embodiments implement two-dimensional matrixes, such as (but not limited to) two-dimensional matrixes of {v, i(E)}ₙ, employed to store electrochemical information for the DL-based analysis. FIG. 4 illustrates a structure of input data, convolutional neural network architecture, and output of electrochemical mechanisms in accordance with an embodiment. FIG. 4 shows a structure of input data and the convolutional neural networks of residual neural network (ResNet) architecture, and the output and utility of DL model for mechanism designation. For the ease of training a ResNet, in each set of {v, i(E)}ₙ the current densities i in voltammograms can be normalized as i_{normalized} against the largest i among all voltammograms in {v, i(E)}ₙ, with i_{normalized} in the forward scan designated as positive values. The electrochemical potentials E can be adjusted so that a 0 V of the adjusted electrochemical potential (E_{adjusted}) roughly corresponds to the potential of various redox couples. Such data processing can ensure a generally readable format of cyclic voltammograms despite the large variations in experimental testing conditions.

Cyclic voltammograms based on the targeted mechanisms (such as the electrochemical mechanisms shown in FIG. 3B) can be numerically simulated as the training set for deep neural networks via the finite-element method. Numerical models of PDEs, boundary conditions, and initial conditions can be constructed based on mechanisms' definitions. Moreover, the numerical models' parameters including (but not limited to) the numbers and values of scan rate v (n=1 to 6), electrodes' double layer capacitance, standard rate constant of interfacial charge transfer in the concentration-dependent Butler-Volmer equation following Nicholson's formalism (ψ∈[10, 0.3]) in the Eᵣ step, and the equilibrium constants and forward/backward rate constants in the Cᵣ step based on Savéant's definitions, can be incorporated into the simulations and carefully constrained with practical and fundamental considerations. The parameters can be randomly sampled for a comprehensive yet even exploration of the mechanism's corresponding domain in the {v, i(E)}ₙ space, i.e. the corresponding kinetic zone diagrams.

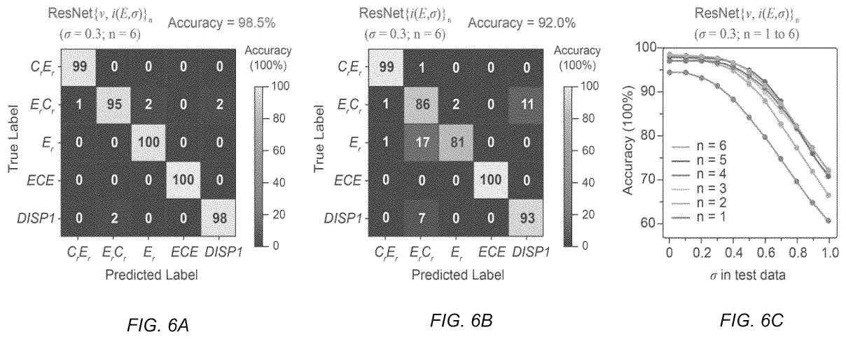

As the experimental voltammograms typically contain Gaussian-type noise due to background and instrumentation, Gaussian noise of varying degrees of standard deviation a relative to the maximal current densities can be added to the simulated voltammograms, resulting in the training set {v, i(E, σ)}ₙ (n=1 to 6). FIGS. 5A-5F illustrate simulated cyclic voltammograms with different levels of Gaussian noises in accordance with an embodiment. The same simulated cyclic voltammograms added with Gaussian noises whose standard deviations a equals to about 0.0 (FIG. 5A), about 0.1 (FIG. 5B), about 0.3 (FIG. 5C), about 0.5 (FIG. 5D), about 0.7 (FIG. 5E), and about 1.0 (FIG. 5F). The voltammograms of the second cycles are displayed. The addition of Gaussian noise can better reflect the realistic electrochemical data and increase the algorithm's tolerance towards noises in automatic mechanism categorization (vide infra).

Several embodiments implement convolutional neural networks such as (but not limited to) ResNet to extract intrinsic features from high-dimensional data. The ResNet architecture utilizes skip connections within its convolutional layers for deeper networks for more feature extraction. Such architecture can be important for training successes as it alleviates the problems of both vanishing and exploding gradients during the training process which mitigates the risk of training failure while maintaining the low overfitting risk inherent of convolutional architectures. The neural network is trained to take either the first or the second cycle of voltammograms for the same electrochemical system at various numbers of different scan rates ({v, i(E, σ)}ₙ, n=1 to 6) and yields the vector y={y₁, y₂, y₃, y₄, y₅}(FIG. 4), in which each component in y is a surrogate of the electrochemical system's probability or fraction towards mechanisms of Eᵣ, EᵣCᵣ, CᵣEᵣ, ECE, and DISP1, respectively. The classification process is completed by designating the mechanism of the largest component in y as a most probable or prominent one for the electrochemical system. Furthermore, the proposed model can estimate the “importance” of different parts of the voltammograms to the prediction, by visualizing the relative magnitudes of gradients of the logits on input data after feeding through the neural network. Such a visual guide of algorithm's “importance” may illustrate how DL models analyze cyclic voltammograms and offer a comparative study between manual inspection and the ResNet-based inspection.

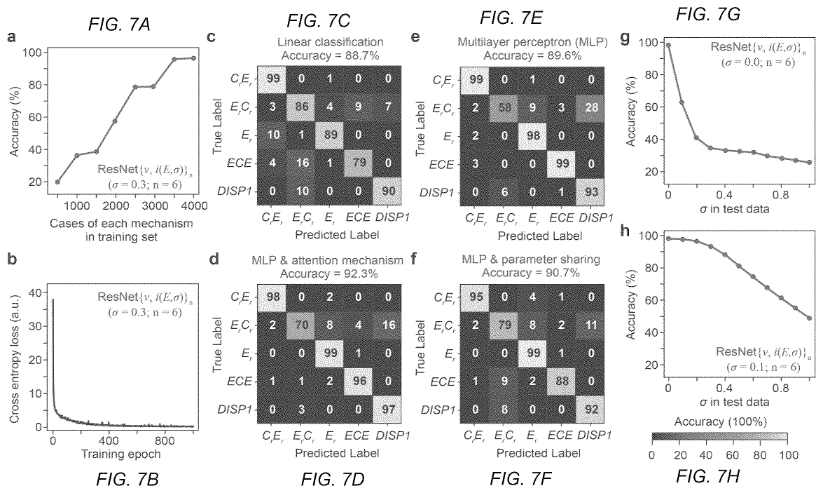

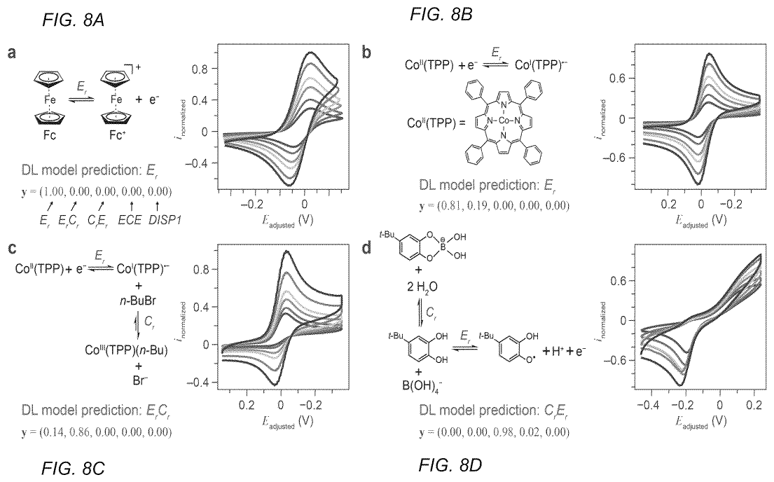

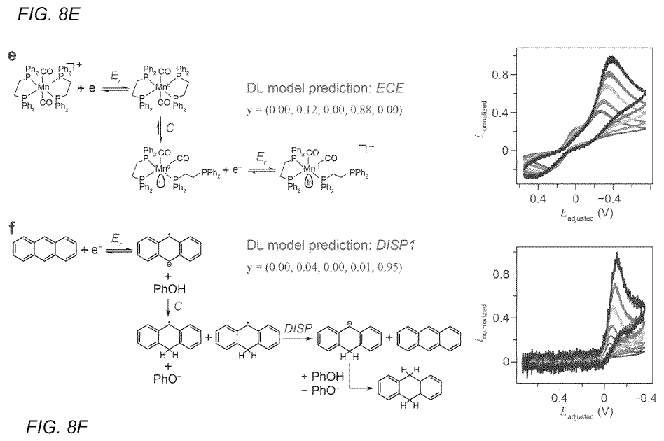

In some embodiments, ResNet models of 18 residual learning layers, i.e. ResNet-18, can be trained and validated by simulated cyclic voltammograms {v, i(E, σ)}ₙ. When n=6 and σ=0.3, satisfactory accuracy (greater than about 90%) can be achieved among {v, i(E, σ)}ₙ when more than 3,000 electrochemical systems are included for each mechanism type in the training set. After 1000 epochs of training to improve accuracy, a voting process that contains eight ResNet-18 models, designated as ResNet{v, i(E, σ)}ₙ, achieves an overall accuracy of about 98.5% for {v, i(E, σ)}ₙ (n=6, σ=0.3) and generates a confusion matrix with nearly zero off-diagonal components. FIG. 6A illustrates a confusion matrix of DL model trained by simulated cyclic voltammograms with explicit values of scan rate (v) as input data in accordance with an embodiment. v is scan rate; σ is the standard deviation of the Gaussian noise; n is the number of v values.

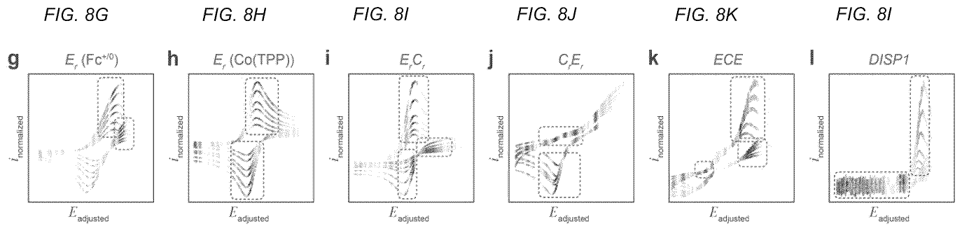

In comparison, alternative machine-learning algorithms including linear classification, the vanilla multilayer perceptron (MLP), the MLP using attention mechanism to aggregate the extracted features of each curve (“MLP & attention mechanism”), and the MLP sharing same parameters/weights on the first layer (“MLP & parameter sharing”) may only yield lower accuracies of about 88.7%, 89.6%, 92.3%, and 90.7%, respectively. FIGS. 7A-7H illustrate training of machine learning algorithms for cyclic voltammetry in accordance with an embodiment. FIG. 7A shows accuracies of RetNet{v, i(E, σ)}ₙ (σ=0.3; n=6) trained by varying numbers of simulated electrochemical systems in each mechanism in the training set. FIG. 7B shows cross entropy loss, a surrogate of the algorithms' accuracy in the training process, as a function of training epochs for ResNet{v, i(E, σ)}ₙ (σ=0.3; n=6). FIGS. 7C, 7D, 7E, and 7F show the confusion matrices and the overall accuracy of various machine-learning models trained by simulated cyclic voltammograms. Training data, {v, i(E, σ)}ₙ (σ=0.3; n=6). FIGS. 7G and 7H show the accuracies of the DL models trained by {v, i(E, σ)}ₙ (σ=0.0; n=6) and v, i(E, σ)}ₙ (σ=0.1; n=6), respectively, when tested with simulated voltammograms with varying values of n and a.

FIG. 6B shows the confusion matrix trained without explicit values of scan rate (v) as input data in accordance with an embodiment. v is scan rate; σ is the standard deviation of the Gaussian noise; n is the number of v values. The DL model is built under the same protocol without the v values as input, ResNet{i(E, σ)}ₙ (n=6, σ=0.3), in which the model's inputs contain the n number of voltammograms but not the exact v values. Only an overall accuracy of 92.0% is achieved and the corresponding confusion matrix contains noticeable non-zero off-diagonal entries. Consistent with manual inspection, the exact values of v are critical in DL to fully differentiate electrochemical mechanisms.

FIG. 6C illustrates the accuracies of the DL model when tested with simulated voltammograms with varying values of n and a in accordance with an embodiment. The DL model is from FIG. 6A. The established DL model is resilient to appreciable degrees of noises in the simulated cyclic voltammograms. The prediction accuracy of the DL model trained by {v, i(E, σ)}ₙ (n=6, σ=0.3) is tested by simulated cyclic voltammograms (n=6) with varying values of a ranging from 0.0 to 1.0. The overall accuracy remains mostly constant and higher than 95% until a 0.5 (purple trace in FIG. 6C). Even at σ=1.0 when the simulated voltammograms are barely recognizable by manual inspection, an overall accuracy of more than 70% can be achieved. Such a tolerance towards noises in cyclic voltammograms is good in comparison to the DL models trained when σ=0.0 (no noise) and 0.1, since in the latter two models (trained with σ=0.0 and 0.1) the overall accuracies quickly drop below 40% and 80%, respectively, at σ=0.5 of the testing data (FIGS. 7G and 7H). The addition of Gaussian noise in model training increases the robustness and sensitivity of the established DL model against data noise that may not be tolerable by manual analysis.

The value of n, i.e., the number of cyclic voltammograms, may affect the overall accuracy of DL models of ResNet architecture. The accuracies of DL models trained by {v, i(E, σ)}ₙ (n=1 to 6, σ=0.3) are tested by simulated voltammograms (n=1 to 6, respectively) of a values ranging from 0.0 to 1.0 (FIG. 6C). When σ<0.5 in the testing data, there is no distinguishable differences in overall accuracies when n=2 to 6 while the accuracies are noticeably lower when n=1 (FIG. 6C). Consistent with the diagnostic value of voltammograms' evolution across different zones in the kinetic zone diagram, cyclic voltammograms of at least two different v values are sufficient for the DL algorithm to accurately designate reaction mechanism within the parameter space defined in the training set.

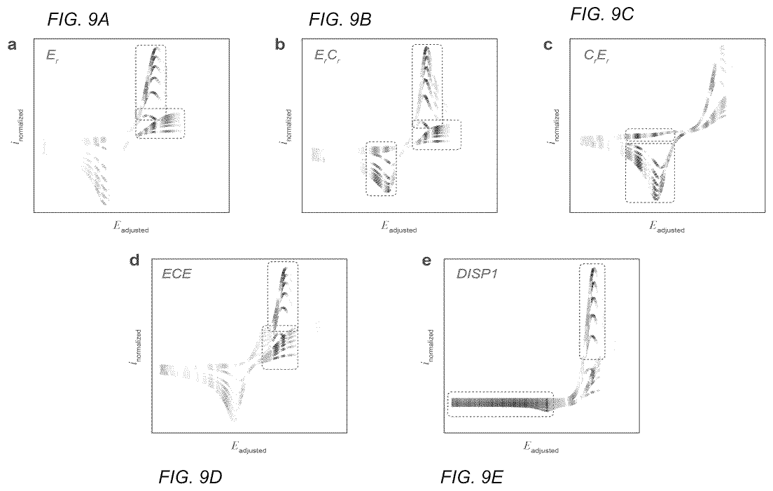

The ResNet-based model can achieve high accuracy of simulated cyclic voltammograms. The established DL models trained by {v, i(E, σ)}ₙ (n=1 to 6, σ=0.3) can be applied to exemplary experimental scenarios mostly based on the voltammograms of the second cycle. FIGS. 8A-8I illustrate DL model predicting electrochemical mechanisms in various experimental scenarios in accordance with an embodiment. The mechanisms, cyclic voltammograms, y vectors from DL model's predictions, and the “importance” plots for 1 mM ferrocene/ferrocenium redox couple (FIGs. A and G), 1 mM tetraphenylporphyrin cobalt(II) (Co^{II}(TPP)) (FIGs. B and H), 1 mM Co^{II}(TPP) and 50 mM 1-bromobutane (n-BuBr) (FIGs. C and I), 1 mM 4-tert-butylcatechol in 10 mM pH 9.2 boric acid buffer (FIGs. D and J), 5 mM trans-Mn(CO)₂(η²-DPPE)₂⁺ (DPPE, 1,2-bis(diphenylphosphino)ethane) (FIGs. E and K), and 1 mM anthracene and 0.1 M phenol (FIGs. F and I). i_{normalized}, normalized current density with the forward scan in the positive direction. E_{adjusted}, electrochemical potential shifted to center the redox features. The “importance” towards the DL model in expected (green) and somewhat unexpected (red) parts in the voltammograms are highlighted. 3 mm glassy carbon; Ag⁺/Ag reference are used, except FIG. 8D uses Ag/AgCl, 3M KCl; Pt wire counter electrode. DMF in Ar is used except FIG. 8D uses water and FIG. 8E uses THF. 0.1 M n-Bu₄NClO₄ in FIGs. A and E, 0.1 M n-Bu₄NPF₆ in FIGs. B, C and E, and 90 mM KCl in FIG. D. The voltammograms of the second cycles, notwithstanding FIG. F (first cycle), are displayed and analyzed. iR corrected. v=0.05, 0.1, 0.2, 0.3, 0.5, 0.7 V/s in FIGs. A-D; v=0.1, 0.2, 0.3, 0.5, 0.7 V/s in FIG. E; v=0.05, 0.1, 0.2, 0.5, 1, 2 V/s in FIG. F. Darker traces in FIGs. G-I indicates higher “importance” in the DL model.

A ResNet-based DL model is capable of accurately predicting the Eᵣ mechanism in the ferrocene/ferrocenium (Fc/Fc⁺, 1 mM) redox couple in dimethylformamide (DMF) (FIG. 8A) and the single-electron Cobalt (II/I) redox couple with tetraphenylporphyrin cobalt(II) (Co^{II}(TPP), 1 mM) as the starting compound in the absence of any electrophiles in DMF (FIG. 8B). The DL model accurately recognizes an EᵣCᵣ mechanism, or more precisely the EᵣCᵢ variant when both the thermodynamic and kinetic propensity of the forward C step is large enough to be considered an irreversible C step, where the addition of 1-bromobutane (n-BuBr, 50 mM) as an electrophile to 1 mM Co^{II}(TPP) in DMF leads to the formation of tetraphenylporphyrin cobalt(III) n-butyl (Co^{III}(TPP)(n-Bu)) (FIG. 8C). The model also accurately recognizes a CᵣEᵣ mechanism for the first single-electron oxidation of 4-tert-butylcatechol (1 mM) in the aqueous buffer of boric acid (pH=9.2, 10 mM), where a reversible Cᵣ step is needed to dissociate the thermodynamically favored catechol-borate adduct into the electrochemically accessible catechol (FIG. 8D). The y vector output from the DL model designates ECE mechanism as the most probable one in the case of 5 mM trans-Mn(CO)₂(η²-DPPE)₂⁺ (DPPE, 1,2-bis(diphenylphosphino)ethane) in tetrahydrofuran (THF), where an intramolecular ligand rearrangement exists between the two single-electron reductions in which the second reduction is thermodynamically more favored than the first one (FIG. 8E). Last, from the first-cycle voltammograms, the DL model accurately designates the DISP1 mechanism in the net two-electron reduction of 1 mM anthracene in DMF with the presence of 0.1 M phenol as proton donor, where disproportionation is known to occur after the reduction of the first electron and the rate-limiting protonation step (FIG. 8F). The successful mechanism designation by the DL models for model experimental systems suggests the practicality of utilizing DL for automatic analysis in cyclic voltammetry.

There are appreciable similarities between the analytic processes of the established DL algorithm and human inspection. The accuracy decreases from 98.5% to 92.0% when the v values are not included as input in the DL model (FIG. 6A and FIG. 6B) is consistent with manual inspection, when more definitive mechanism assignment is feasible when the explicit v values are included in the analysis. Indeed, the exclusion of v values as model input deteriorates the model's accuracies mostly by mis-assigning Eᵣ as EᵣCᵣ and mis-assigning EᵣCᵣ as DISP1 (increasing from 0% chance to 17% and from 2% to 11%, respectively, from FIG. 2c to FIG. 2d). These mis-assignments are common when v information is missing in manual analysis, owing to the gradual transition of cyclic voltammograms between Eᵣ and EᵣCᵣ in the kinetic zone diagrams as well as the similarity between the one-electron EᵣCᵢ and two-electron DISP1 processes. The ResNet-based model's dependence of prediction accuracies on n (FIG. 6C) is understandable yet informative. Statistically in most scenarios two cyclic voltammograms of different v values may suffice and there are diminishing returns of prediction accuracy when n≥2 within the parameter space defined in the training set of simulated voltammograms. When n=2, the corresponding mathematical requirements for the two v values can be decided to be satisfied in the training data set hence empirically offer good accuracy of mechanistic prediction from the DL model. Such mathematical relationships will be helpful when deciding experimental parameters in cyclic voltammetry.

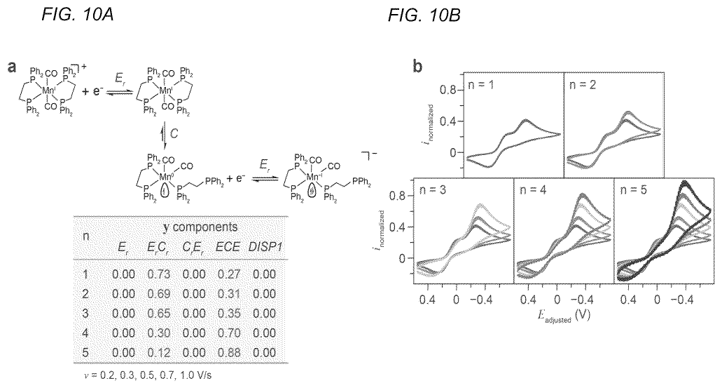

Plotting the algorithm's “importance” towards parts of cyclic voltammograms suggests that there is additional information in subtle voltammogram features that may elude manual inspection. FIGS. 8G-8I plot the “importance” distributions in cyclic voltammograms from the DL model shown in FIGS. 8A-8F, respectively. FIGS. 9A-9E illustrate the “importance” plots of simulated cyclic voltammograms in accordance with an embodiment. Exemplary simulated cyclic voltammograms (σ=0.0) and the corresponding “importance” in ResNet{v, i(E, σ)}ₙ (σ=0.3; n=6) for Eᵣ (FIG. 9A), EᵣCᵣ (FIG. 9B), CᵣEᵣ (FIG. 9C), ECE (FIG. 9D), and DISP1 (FIG. 9E) mechanisms. The “importance” towards the DL model in expected (green) and somewhat unexpected (red) parts in the voltammograms are highlighted. The voltammograms of the second cycles are displayed and analyzed.

While an understandable amount of the model's attention is attributed to presence or absence of primary redox peaks in voltammograms (green areas in FIGS. 8G-9E), one feature unique to DL algorithm emerges. Appreciable amount of “importance” of the DL model is frequently assigned to the reverse scan roughly beneath the redox peaks (red areas in FIGS. 8G-9E), an area typically not carefully examined in manual inspection. Such seldomly examined regions in cyclic voltammograms may contain useful mechanistic information and ought to be better utilized for mechanistic studies, probably by DL-based automatic analysis thanks to the algorithm's sensitivity.

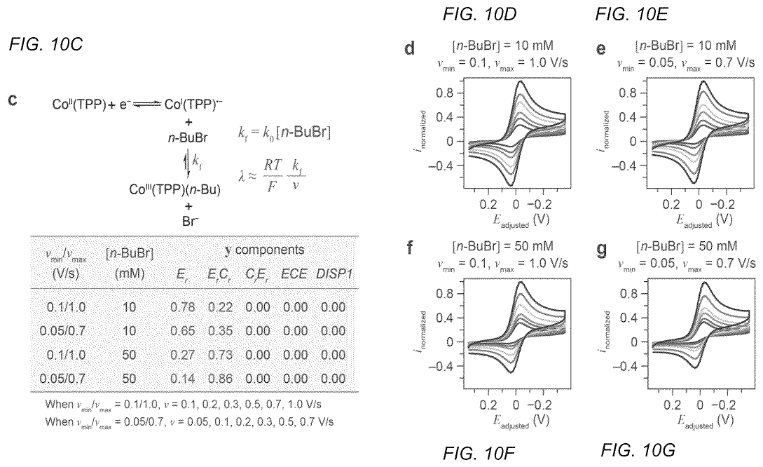

In the predominantly ECE case of trans-Mn(CO)₂(η²-DPPE)₂⁺ in THF, the evolution of y vector as n increases illustrates how more definitive mechanism determination in edge cases will benefit from cyclic voltammograms of multiple v values. FIGS. 10A-10G illustrate semi-qualitative analysis of cyclic voltammograms with DL algorithm in accordance with an embodiment. FIG. 10A shows the mechanism and y vector components for the ECE scenario of trans-Mn(CO)₂(η²-DPPE)₂⁺. FIG. 10B shows cyclic voltammograms of 5 mM trans-Mn(CO)₂(η²-DPPE)₂⁺ for different n values under the same conditions in FIG. 8F. With additional voltammograms, the EᵣCᵣ component in yielded y vector decreases from 0.73 (n=1) to 0.12 (n=5) while the ECE one increases from 0.27 (n=1) to 0.88 (n=5) (FIG. 4b). Such changes in y components as a function of n is consistent with the reported challenges in differentiating EᵣCᵣ and ECE/DISP1 mechanisms with a small number of v.²

The output y vector from the DL model can be utilized to provide additional semi-quantitative analysis in addition to its function of designating the most probable mechanism. Non-zero probabilities/fractions for mechanisms other than the most probable/prominent one may suggest either a competing reaction or a gradual transition from one mechanism to another. FIG. 10C shows the mechanism, kinetic factors, and y vector components for the EᵣCᵣ scenario of Co^{II}(TPP) and n-BuBr. FIGS. 10D-10G show cyclic voltammograms of 1 mM Co^{II}(TPP) under different v ranges and n-BuBr concentrations ([n-BuBr]) under the same conditions in FIG. 8C. The voltammograms of the second cycles are displayed and analyzed. In the one-electron reduction of Co^{II}(TPP) in the presence of n-BuBr (FIG. 10C), the forward Cᵣ step, namely the nucleophilic attack of Co^{I}(TPP)·⁻ towards n-BuBr, is pseudo-first-order on the concentration of n-BuBr ([n-BuBr]) and the forward rate constant k_{f} is proportional to [n-BuBr]. The corresponding dimensionless kinetic parameter λ, proportional to k_{f}/v (FIG. 10C), measures the competition between the solution reaction and redox diffusion from/to the electrode surface. As [n-BuBr]increases or v decreases, A is larger and leads to more pronounced “irreversibility” from the Cᵣ step in the voltammograms. Experimentally, the cyclic voltammograms display a smaller tendency of reoxidation of Co^{I}(TPP)·⁻ when [n-BuBr] increases from 10 mM (FIGS. 10D and 10E) to 50 mM (FIGS. 10F and 10G), and when the range of v values decreases from v E [0.1, 1.0]V/s (FIGS. 4d and 4f) to v E [0.05, 0.7]V/s (FIGS. 10E and 10G). Accordingly, as shown in FIG. 10C, the EᵣCᵣ component in the yielded y vectors gradually increased from 0.22 for FIG. 10D to 0.86 for FIG. 10F, while the component for Eᵣ correspondingly decreases from 0.78 to 0.14. Such results indicate that the DL model is capable of semi-quantitatively detecting the extent and gradual increase of Cᵣ step, which could be valuable when studying systems with undesirable deactivation in redox cycling or desirable chemical transformation, amid an Eᵣ system.

### EXEMPLARY EMBODIMENTS

The following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g., amounts, temperature, etc.) but some experimental errors and deviations should be accounted for.

### Example 1: Finite-Element Simulation of Cyclic Voltammograms

Finite-element simulations of cyclic voltammograms are conducted using COMSOL Multiphysics v5.5. The modules of Electrochemistry and Chemical Reaction Engineering are used for a one-dimensional model under the supporting electrolyte assumption with a time-dependent solver specialized for cyclic voltammetry, using an adaptive mesh with a maximal mesh size of 41 μm and a growth rate of 1.3. COMSOL simulations were iterated using COMSOL LiveLink™ which implements MATLAB R2020b. Random samples of variables are realized by Python 3 scripts and fed to COMSOL via MATLAB for the simulations of at least five consecutive cycles in cyclic voltammetry. Additional sanitization is implemented after COMSOL simulation to ensure the simulated cyclic voltammograms not only satisfy the corresponding mechanism but also are electrochemically accessible. A total of about 15,000 valid simulated cases, each containing cyclic voltammograms up to 6 different v values, are conducted.

### Example 2: Establishment of Machine-Learning Algorithm

Simulated and experimental data is sanitized and translated in to the two-dimensional matrix {v, i(E)}ₙ before the implementation of machine learning. For each data point that is comprised of either simulated or experimental cyclic voltammograms at n number of v values ({v, i(E)}ₙ), the current densities i in voltammograms are normalized as i_{normalized} against the largest i among all voltammograms in {v, i(E)}ₙ, with i_{normalized} in the forward scan designated as positive value. The electrochemical potentials E are adjusted so that the adjusted electrochemical potential E_{adjusted}=0 V roughly corresponds to the potential of studied redox couple. For voltammograms in which irreversibility precludes an accurate determination of redox potential, a rough estimate is automatically conducted based on the largest slope of the first rising redox peak. Interpolation and/or imputation of the i-E characteristics are conducted so that the two-dimensional matrix as input of the machine-learning model does not explicitly contain the information of E. Therefore, the use of E_{adjusted} is mostly for presentation purpose because the absolute values of E_{adjusted} are not inputs of the machine-learning model hence are not directly relevant to the automatic mechanistic analysis.

Machine-learning code is implemented on Jupyter notebooks using Python3 code. PyTorch machine learning frameworks are used to implement the various neural networks discussed in this work. The DL algorithms are trained to take either the first or second cycles of voltammograms for the same electrochemical system at various numbers of different scan rates ({v, i(E, σ)}ₙ, n=1 to 6, σ=0.0 to 1.0) and yields the vector y={y₁, y₂, y₃, y₄, y₅}. Because different starting potentials of voltammograms create additional variations for the first cycle of the voltammograms in both simulated and experimental scenarios, algorithms trained by the second cycles of voltammograms are used for the results reported here. Graphs were generated using the MatPlotLib library and the PyPlot module. Training data is input with stochastically added noise to increase the robustness of the model to the noise encountered in real experimental data. Final classifications are dictated by eight trained ResNet-18 models voting on final classification to decrease the effect of randomness in individual model training.

### Example 3: Experiments of Electrochemical Characterization

The tetraphenylporphyrin cobalt(II) (Co^{II}(TPP)) (80%), tetra-n-butylammonium hexafluorophosphate (n-Bu₄NPF₆) (98%) and tetra-n-butylammonium perchlorate (n-Bu₄NClO₄) (98%) are purchased from TCI America; anhydrous diethyl ether is purchased from Fisher Scientific; ferrocenium (Fc⁺) hexafluorophosphate (98%) is purchased from Santa-Cruz Biotechnology; 1-bromobutane (n-BuBr) (99%), anhydrous N,N-dimethylformamide (DMF), anhydrous benzene, anhydrous acetonitrile, anhydrous tetrahydrofuran (THF), anhydrous dichloromethane, anhydrous pentane, dimanganese(0) decacarbonyl (98%), ethylenebis(diphenylphosphine) (99%), boric acid (99.5%), potassium chloride (99%), sodium hydroxide (99%) and 4-tert-butylcatechol (97%, HPLC) are purchased from Sigma-Aldrich. All the chemicals are used as received unless otherwise specified below. Bu₄NPF₆ and Bu₄NClO₄ salts are recrystallized from ethanol before use. Co^{II}(TPP) is recrystallized from methylene chloride before use. n-BuBr is fractionally distilled over CaSO₄ under N₂ at atmospheric pressure. The second fraction is collected at 102° C. and is dried over molecular sieves before use. THF is dried over molecular sieves before use. 4-tert-butylcatechol is distilled under reduced pressure and is allowed to recrystallize under vacuum at room temperature as a white crystalline solid before use.

The Mn complex [trans-Mn(CO)₂(DPPE)₂]PF₆ is synthesized. Dimanganese(0) decacarbonyl (0.2 g, 0.5 mmol) and DPPE (DPPE=ethylenebis(diphenylphosphine), 0.4 g, 1 mmol) are dissolved in 10 mL of benzene and the solution is refluxed under N₂ for 4 hrs. The [trans-Mn(CO)₂(DPPE)][Mn(CO)₅] salt is formed and collected as a yellowish solid. A portion of this solid (0.11 g, 0.1 mmol) is dissolved in 3 mL acetonitrile and 1 equivalent ferrocenium hexafluorophosphate (0.033 g, 0.1 mmol) is added to this solution and the reaction mixture is stirred vigorously for 30 min. Layering diethyl ether over this reaction mixture afforded an orange-yellow solid, which upon further recrystallization with dichloromethane/pentane afforded an orange-yellow crystalline solid (0.06 g, 59%). ³¹P NMR (CDCl₃): δ 77.9 ppm (s) and −144.3 ppm (m).

Experiments of cyclic voltammetry are performed at room temperature using a CH Instruments 630D potentiostat. Solutions in organic solvents are performed under an Ar atmosphere in a glovebox (Vigor SG1200/750TS), while aqueous experiments are performed under N₂ atmosphere. iR corrections are conducted with positive feedback compensations for the ohmic drop. Ag/Ag⁺ pseudo-reference electrode is calibrated against Fc⁺/Fc redox after electrochemical measurements.

### Example 4: General Considerations for the Model of Cyclic Voltammetry

A time-dependent one-dimensional model is established under the supporting electrolyte assumption for the COMSOL-based finite-element simulation of cyclic voltammograms. The model numerically simulates the oxidative electrochemical systems, in which before cyclic voltammetry only the reduced species (R) are present in the solution. Only the oxidative electrochemical processes may be needed in the training model thanks to the process of data pre-treatment and sanitization. Below are the boundary and initial conditions in specific mechanistic scenarios. The ranges in variable's values and the sampling method (linearly or logarithmically) are discussed and summarized in Table 1. As shown below, the range in variable's values could be interdependent. Such interdependence and random sampling are implemented by python 3 scripts.

### Example 4.1: Partial Differential Equations

$$\frac{\partial {C}_{i}}{\partial t} = {D}_{i} \frac{{\partial }^{2} {C}_{i}}{\partial {x}^{2}} + {f}_{i} \qquad ( 1 )$$

Here fₗ denotes the mechanism-specific function that describes any possible C step in the solution. fᵢ=0 denotes the absence of any homogenous C steps.

The diffusion coefficients Di, sampled logarithmically, are assumed to be same D for all the molecular redox species in the solution.

The initial concentration of the reduced species C_{R,i} is linearly sampled from 0.1 mM to 100 mM with additional constrains listed below.

### Example 4.2: Boundary and Initial Conditions

Diffusion layer assumption is implemented in the simulation. A finite diffusion layer L is implemented so that x=0 denotes the electrode and x=L denotes the boundary diffusion layer. In Nicholson's formalism of cyclic voltammetry and presented below for single-electron transfer from O to R with the period of triangular voltage wave as λ, function S_{λ}(t) describes the temporal concentration variation of O in the presence of diffusion for each period of triangular voltage wave,

$${D}_{O} \frac{\partial [ O ]}{\partial x} = {{{k}_{s} ( \frac{{C}_{O , i}}{{C}_{R , i}} )}^{- α} [ {S}_{λ} ( t ) ]}^{- α} [ {[ O ]}_{x = 0} - \frac{{C}_{O , i}}{{C}_{R , i}} {{S}_{λ} ( t ) [ R ]}_{x = 0} ] \\ {S}_{λ} ( t ) = \{ \begin{matrix}{e}^{- at} , & t < λ \\ {e}^{at - 2 aλ} , & t > λ\end{matrix} , a = \frac{Fv}{RT}$$

in which kₛ is the standard rate constant of interfacial charge transfer and α=0.5 is the transfer coefficient.

The above expression suggests that the characteristic time constant of diffusional behavior is RT/Fv for S_{λ}(t). Therefore, in our simulation, the thickness of the diffusion layer L is adaptively chosen so that the L is more than six times of the characteristic length scale of diffusion within the noted characteristic time constant when T=298.15 K (same below).

$$L = 6 \sqrt{D \cdot \frac{RT}{Fv}} \qquad ( 2 )$$

Here the scan rate v is evenly sampled both logarithmically and linearly between 0.01 to 2 V/s. Additional algorithms to sample n number of different v values in the same simulated electrochemical systems is extensively discussed below.

In addition to the Faradaic processes simulated below, capacitive double-layer charging events are also simulated with double-layer capacitance C_{dl} randomly sampled linearly between 5 to 35 μF/cm².

### Example 4.3: Eᵣ Mechanism

$${E}_{r} : R {↔}^{E} O + {e}^{-} \\ {f}_{R} = 0 , {f}_{O} = 0 in eq . ( 1 ) . {[ R ]}_{t = 0} = {C}_{R , i} , {[ O ]}_{t = 0} = 0$$

The thermodynamic potential of O/R redox E_{O/R}=0 V versus an arbitrary reference electrode. The cyclic voltammograms are simulated with a potential window in which the anodic bound E_{window,a} is linearly sampled between 0.5 and 1 V vs. NHE and the cathodic bound E_{window,c} is linearly sampled between −0.5 and −1 V vs. NHE. The starting potential of the cyclic voltammogram Eₛₜₐᵣₜ is linearly sampled between −0.2 V vs. NHE and E_{window,c}. Such an arrangement of Eₛₜₐᵣₜ ensures that there is minimal transient current at the beginning of voltage sweep.

Concentration-dependent Butler-Volmer equation¹ is employed to define the Eᵣ step at the electrode interface.

$$i ( t ) = {i}_{0} \{ \frac{{[ R ]}_{x = 0}}{0.5 \cdot {C}_{R , i}} exp [ \frac{α F}{RT} ( E - {E}_{O / R} ) ] - \frac{{[ O ]}_{x = 0}}{0.5 \cdot {C}_{R , i}} exp [ - \frac{( 1 - α ) F}{RT} ( E - {E}_{O / R} ) ] \} \qquad ( 3 )$$

Here, α=½ and 0.5·C_{R,i} denotes the equilibrium concentration when E=E_{O/R} and C_{R}=C_{O}. The exchange current density i₀ is logarithmically sampled with the upper-bound i_{o,upper} and lower-bound i_{o,lower}.

Following the Nicholson's formalism in cyclic voltammetry, i₀ is dependent on the standard rate constant of surface change transfer kₛ:

$${i}_{0} = {k}_{s} \cdot 0.5 {FC}_{R , i} = ψ \sqrt{\frac{π F v D}{R T}} \cdot 0.5 {FC}_{R , i} \qquad ( 4 )$$

ψ∈[10, 0.3] can be used following the Nicholson's formalism, which corresponding to a peak separation ΔEₚ=62˜120 mV in the cyclic voltammograms. The upper bound of ψ values may be high enough that the resultant scenarios resemble the Nernstian scenario in cyclic voltammetry in which the interfacial charge transfer is fast enough to ensure a Nernstian equilibrium for the redox species in the immediate proximity near the electrode.

$${i}_{0 , upper} = 10 \cdot 0.5 {FC}_{R , i} \sqrt{\frac{π FvD}{RT}} \qquad ( 5 a )$$

$${i}_{0 , lower} = 0.3 \cdot 0.5 {FC}_{R , i} \sqrt{\frac{π FvD}{RT}} \qquad ( 5 b )$$

As to ensure detectable peaks in cyclic voltammograms, additional constraint about the minimal concentration of redox O/R (C_{R,i}) are needed. The current densities of the redox peaks can be estimated based on Randle-Sevcik equation and ensure that the estimated current densities are at least about 5 times of the background current density from the capacitive double-layer charging/discharging.

$${C}_{R , i , min} = max \{ 0.1 mM , \frac{5}{0.446 F} {C}_{dl} v \sqrt{\frac{RT}{FvD}} \} \qquad ( 6 )$$

### Example 4.4: EᵣCᵣ Mechanism

$${E}_{r} : R {↔}^{E} O + {e}^{-} \\ {C}_{r} : O {↔}^{C} A \\ {f}_{R} = 0 , {f}_{O} = {k}_{b} [ A ] - {k}_{f} [ O ] , {f}_{A} = {k}_{f} [ O ] - {k}_{b} [ A ] in eq . ( 1 ) . {K}_{O / A} ≡ {\frac{{k}_{f}}{{k}_{b}} [ R ]}_{t = 0} = {C}_{R , i} , {[ O ]}_{t = 0} = 0 , {[ A ]}_{t = 0} = 0 .$$

Most of the constraints in the EᵣCᵣ mechanism are the same as the Eᵣ mechanism with the following additional constraints.

The equilibrium constant of the Cᵣ step K_{O/A} is logarithmically sampled between 10^{0.5}˜10³.

The kinetic rate constant of Cᵣ step in the forward direction k_{f} is logarithmically sampled within the following upper and lower bound so that log₁₀

$$λ ≡ {log}_{10} ( \frac{R T}{F} \frac{{k}_{f} + {k}_{b}}{v} ) ∈ [ - 2 , 4.5 ] .$$

$${k}_{f , upper} = 1 {0}^{4.5} \cdot \frac{F}{RT} \cdot \frac{v {K}_{O / A}}{{K}_{O / A} + 1} \qquad ( 7 a )$$

$${k}_{f , lower} = 1 {0}^{- 2} \cdot \frac{F}{RT} \cdot \frac{v {K}_{O / A}}{{K}_{O / A} + 1} \qquad ( 7 b )$$

The above ranges of K_{O/A} and k_{f} values capture all of the possible variations in the EᵣCᵣ mechanism, before the small value of K_{O/A} leads to situations that are indeed the Eᵣ mechanism and presented at the very upper part of that figure.

Because of the resultant potential shifts of redox peaks in the EᵣCᵣ mechanism, the Eₛₜₐᵣₜ is now linearly sampled between E_{window,c} and −0.2−0.059 log₁₀ K_{O/A}V vs. NHE.

### Example 4.5: CᵣEᵣ Mechanism

$${C}_{r} : A {↔}^{C} R \\ {E}_{r} : R {↔}^{E} 0 + {e}^{-} \\ {f}_{A} = {k}_{b} [ R ] - {k}_{f} [ A ] , {f}_{R} = {k}_{f} [ A ] - {k}_{b} [ R ] , {f}_{O} = 0 in eq . ( 1 ) . {K}_{R / A} ≡ {\frac{{k}_{f}}{{k}_{b}} [ A ]}_{t = 0} = {C}_{R , i} \frac{1}{{K}_{R / A} + 1} , {[ R ]}_{t = 0} = {C}_{R , i} \frac{{K}_{R / A}}{{K}_{R / A} + 1} , {[ O ]}_{t = 0} = 0 .$$

Most of the constraints in the CᵣEᵣ mechanism are the same as the Eᵣ mechanism with the following additional constraints.

The equilibrium constant of the Cᵣ step K_{R/A} is logarithmically sampled between 10⁻³˜10^{-0.5}.

The kinetic rate constant of Cᵣ step in the forward direction k_{f} is logarithmically sampled within the following upper and lower bound so that log₁₀

$$λ ≡ {log}_{10} ( \frac{R T}{F} \frac{{k}_{f} + {k}_{b}}{v} ) ∈ [ - 2 , 4.5 ] .$$

$${k}_{f , upper} = 1 {0}^{4.5} \cdot \frac{F}{R T} \cdot \frac{v {K}_{R / A}}{{K}_{R / A} + 1} \qquad ( 8 a )$$

$${k}_{f , l o w e r} = 1 {0}^{- 2} \cdot \frac{F}{R T} \cdot \frac{v {K}_{R / A}}{{K}_{R / A} + 1} \qquad ( 8 b )$$

The above ranges of K_{R/A} and k_{f} values capture all of the possible variations in the CᵣEᵣ mechanism, before the large value of K_{R/A} leads to situations that are indeed the Eᵣ mechanism and presented at the very upper part of that figure.

Because of the resultant potential shifts of redox peaks in the CᵣEᵣ mechanism, the anodic bound of electrochemical window E_{window,a} is now linearly sampled between 0.5+0.059 log₁₀ K_{R/A} and 1.0+0.059 log₁₀ K_{R/A} V vs. NHE, and the Eₛₜₐᵣₜ is now linearly sampled between E_{window,c} and −0.2+0.059 log₁₀ K_{R/A} V vs. NHE.

### Example 4.6: ECE Mechanism

$${E}_{r} : R 1 {⟷}^{E} O 1 + {e}^{-}$$

$$C : O 1 {⟶}^{C} R 2$$

$${E}_{r} : R 2 {⟷}^{E} O 2 + {e}^{-}$$

$${f}_{R 1} = 0 , {f}_{O 1} = - k [ O 1 ] , {f}_{R 2} = k [ O 1 ] , {f}_{O 2} = 0 in eq . ( 1 ) .$$

$${[ R 1 ]}_{t = 0} = {C}_{R , i} , {[ O 1 ]}_{t = 0} = 0 , {[ R 2 ]}_{t = 0} = 0 , {[ O 2 ]}_{t = 0} = 0 .$$

The Eᵣ step between R1 and O1 follows the same definition of R and C in the Eᵣ mechanism.

The kinetic rate constant k of the C step is logarithmically sampled with the following constraints so that log₁₀

$$λ ≡ {log}_{10} ( \frac{R T}{F} \frac{k}{v} ) ∈ [ - 1 , 3 ]$$

$${k}_{upper} = 1 {0}^{3} \frac{F}{R T} v \qquad ( 9 a )$$

$${k}_{l o w e r} = 1 {0}^{- 1} \frac{F}{R T} v \qquad ( 9 b )$$

The selection of above k range covers almost all of the possible variations in the ECE mechanism.

The Eᵣ step between R2 and O2 are defined with its thermodynamic redox potential E_{O2/R2} linearly sampled between −0.7 and −0.1 V vs. NHE. The electrochemical kinetics of the Eᵣ step is defined as a concentration dependent Butler-Volmer process illustrated in eq. (3). The standard rate constant of surface change transfer k_{s,O2/R2} and the corresponding exchange current density i_{0,O2/R2} is defined and sampled similarly as the i₀ in the Eᵣ mechanism.

$${i}_{0 , O 2 / R 2} = {k}_{s , O 2 / R 2} \cdot 0.5 {FC}_{R , i} = {ψ}^{′} \sqrt{\frac{π FvD}{R T}} \cdot 0.5 {FC}_{R , i} \qquad ( 10 )$$

When ψ′ was chose as ψ′∈[10, 0.3], we have,

$${i}_{0 , O 2 / R 2 , upper} = 10 \cdot 0.5 {FC}_{R , i} \sqrt{\frac{π FvD}{R T}} \qquad ( 11 a )$$

$${i}_{0 , O 2 / R 2 , lower} = 0.3 \cdot 0.5 {FC}_{R , i} \sqrt{\frac{π FvD}{R T}} \qquad ( 11 b )$$

In order to accommodate the additional redox features, the Eₛₜₐᵣₜ is now linearly sampled between E_{window,c} and −0.6 V vs. NHE.

### Example 4.7: DISP1 Mechanism

$${E}_{r} : R 1 {⟷}^{E} O 1 + {e}^{-}$$

$$C : O 1 {⟶}^{C} R 2$$

$$DISP : R 2 + O 1 {⟶}^{DISP} O 2 + R 1$$

$${f}_{R 1} = {k}_{DISP} [ R 2 ] [ O 1 ] , {f}_{O 1} = - k [ O 1 ] - {k}_{DISP} [ R 2 ] [ O 1 ] , {f}_{R 2} = k [ O 1 ] - {k}_{DISP} [ R 2 ] [ O 1 ] , {f}_{O 2} = {k}_{DISP} [ R 2 ] [ O 1 ] in eq . ( 1 ) .$$

$${[ R 1 ]}_{t = 0} = {C}_{R , i} , {[ O 1 ]}_{t = 0} = 0 , {[ R 2 ]}_{t = 0} = 0 , {[ O 2 ]}_{t = 0} = 0 .$$

The Eᵣ step between R1 and O1 follows the same definition of R and C in the Eᵣ mechanism.

The Eₛₜₐᵣₜ and the kinetic rate constant k of the C step follow the same definition of k in the ECE mechanism.

The kinetic rate constant k_{DISP} of the DISP step is logarithmically sampled with the following constraints.

$${k}_{DISP , upper} = 1 {0}^{2} \frac{{k}^{3 / 2}}{{C}_{R , i}} \sqrt{\frac{R T}{F v}} \qquad ( 12 a )$$

$${k}_{DISP , upper} = 1 {0}^{- 2} \frac{{k}^{3 / 2}}{{C}_{R , i}} \sqrt{\frac{R T}{F v}} \qquad ( 12 b )$$

The above definition of k_{DISP} covers almost the full phase diagram since the corresponding

$${p}_{E C E}^{DISP} ,$$

defined below, is within the range of [10⁻², 10²].

$${p}_{E C E}^{DISP} = \frac{{k}_{DISP}}{{k}^{3 / 2}} {C}_{R , i} \sqrt{\frac{F v}{R T}}$$

The above definition indeed may also include scenarios that is similar, but not quite the same, to the DISP2 mechanism, when the DISP step is slow and rate-limiting (yet the limiting case of DISP2 mechanism requires a reversible pre-equilibrium for the C step between O1 and R2). Such slight ambiguity of simulated voltammograms in the training data will be addressed in future versions of the algorithm.

### Example 4.8: Additional Considerations when Sampling Scan Rate v

In the sampling of simulated cyclic voltammograms, variables intrinsic to the chemistry of the electrochemical systems are first sampled either linearly or logarithmically. Variables related to the electrochemical testing conditions, including Eₛₜₐᵣₜ, E_{window,a}, E_{window,c}, and v are sampled subsequently. Particular attention is paid to the sampling of v since multiple chemistry-intrinsic variables are also dependent on the v values as shown in Table 1. Aiming to obtain up to 6 simulated cyclic voltammograms with different v values (n=6), an iterative process of variable samplings is implemented in the python 3 scripts as shown below.

Step 1: After the initial generation of random combinations of chemistry-related variables listed in Table 1, a medium scan rate v_{medium} is linearly sampled between 0.1 to 0.5 V/s, the range of v mostly commonly used in cyclic voltammetry. As shown below v_{medium} serves as a temporal variable in the selection of v values and is not numerically used in simulation. The current densities of the redox peak are roughly estimated based on the Randle-Sevcik equation.

$${i}_{medium} = 0.446 {C}_{R , i} \sqrt{\frac{{FDv}_{m e d i u m}}{R T}} \qquad ( 13 )$$

Step 2. The maximal and minimal scan rate vₘₐₓ and vₘᵢₙ are randomly selected based on the following constraints.

$${v}_{max} = min \{ 2 , \frac{R T}{π FD} {( \frac{10 {i}_{0}}{F {C}_{R , i}} )}^{2} , \frac{F D}{R T} {( \frac{0.4 \; 46 {FC}_{R , i}}{5 {C}_{d l}} )}^{2} , {10}^{0.6} \cdot {i}_{medium} \} \qquad ( 14 a )$$

$${v}_{min} = max \{ 0.01 , \frac{R T}{π FD} {( \frac{{i}_{0}}{10 {FC}_{R , i}} )}^{2} , {10}^{- 0.6} \cdot {i}_{medium} \} \qquad ( 14 b )$$

The above constraints ensure that vₘₐₓ and vₘᵢₙ are within the ranges of 0.01 to 2 V/s, the peak separations in the Nicholson's formalism will not deviate too much from the targeted values separation (ΔE_{P}=62˜120 mV), the voltammograms at maximal scan rates won't lead to indistinguishable redox peaks due to capacitive double-layer charging/discharging, and there is significant differences, 10^{0.6}˜4 fold difference in current densities, among the n number of simulated cyclic voltammograms.

Step 3. If vₘₐₓ−vₘᵢₙ≤0.5 V/s, go back to Step 1 again. Otherwise, proceed to Step 4.

Step 4. 4 more additional v values are linearly or logarithmically sampled between the vₘₐₓ and vₘᵢₙ, leading to 6 values of v in total (n=6).

### Example 5: The Number of Voltammograms n Needed for Mechanism Determination

As discussed above, when n≥2 the prediction accuracies of DL models trained by {v, i(E, σ)}ₙ (n=1 to 6, σ=0.3) more or less remain equally satisfactory (>95%). Such results suggest that within the tested set of simulated voltammograms, statistically on average there is diminishing returns of prediction accuracy when n>2.

In Example 4, the procedures of selecting the maximal and minimal values of v in the training set of simulated voltammograms are reported. When n=2, there may exist the following approximate relationship between the two v values (v_{high} and v_{low}) and the medium value v_{medium}:

$${v}_{m e d i u m} \approx \frac{{v}_{h i g h} + {v}_{l o w}}{2} ∈ [ 0.1 , 0 \text{.5} ] V / s \qquad ( 15 )$$

Here the “≈” sign suggests that the above relationship is a statistically approximation given that v_{high} and v_{low} are randomly sampled around the value of v_{medium}.

Hence, the approximate range of v_{high} and v_{low} can be defined as:

$${v}_{h i g h} = min \{ 2 , \frac{R T}{π FD} {( \frac{10 {i}_{0}}{F {C}_{R , i}} )}^{2} , \frac{FD}{RT} {( \frac{0.4 \; 46 {FC}_{R , i}}{5 {C}_{d l}} )}^{2} , {10}^{0.6} \cdot 0.446 {C}_{R , i} \sqrt{\frac{F D ( {v}_{h i g h} + {v}_{l o w} )}{2 RT}} \} , \qquad ( 16 a )$$

$${v}_{l o w} = max \{ 0.01 , \frac{R T}{π FD} {( \frac{{i}_{0}}{10 {FC}_{R , i}} )}^{2} , 1 {0}^{- 0.6} \cdot 0.446 {C}_{R , i} \sqrt{\frac{F D ( {v}_{h i g h} + {v}_{l o w} )}{2 RT}} \} , \qquad ( 16 b )$$

$${v}_{max} - {v}_{min} \leq 0.5 V / s \qquad ( 16 c )$$

Equations (16a), (16b), and (16c) provide an approximate empirical range of v_{high} and v_{low} values in order to satisfy the defined training data set of voltammograms and hence offer good accuracy of mechanistic prediction based on our DL model. The above relationships indicate that v_{high} and v_{low} values are dependent on the redox species' concentration (C_{R,i}) and diffusion coefficient (D), the electrodes' double-layer capacitance (C_{dl}), and the exchange current density (i₀) hence the standard rate constant of interfacial charge transfer (kₛ) based on equation (4). A combination of experimental parameters (C_{R,i} and C_{dl}) and redox's intrinsic properties (D and kₛ) determines the values of v_{high} and v_{low} for effective discernment of electrochemical mechanisms.

TABLE 1
The variables and the corresponding value ranges in the numerical simulation

| Variable | Value ranges | Constraints |
|---|---|---|
| Eᵣ mechanism | | |
| V | 0.01~2 V/s ^{a,b} | Default setting, see specific mechanisms below if noted |
| C_{R,i} | C_{R,i,min}~100 mM ^{a} | ${C}_{R , i , min} = max \{ 0.1 mM , \frac{5}{0.446 F} {C}_{dl} v \sqrt{\frac{R T}{F v D}} \}$ |
| D | 1 × 10⁻⁷~1 × 10⁻⁴ cm²/s ^{a,c} | |
| L | N.A. | $L = 6 \sqrt{D \cdot \frac{RT}{Fv}}$ |
| C_{dl} | 5~35 μF/cm^{2 b} | |
| E_{window,a} | 0.5~1 V vs. NHE ^{b} | Default setting, see specific mechanisms below if noted |
| E_{window,c} | −0.9~−1.4 V vs. NHE ^{b} | |
| Eₛₜₐᵣₜ | E_{window,c}~−0.2 V vs. NHE ^{b} | Default setting, see specific mechanisms below if noted |
| i₀ | i_{0,lower}~i_{0,upper a} | ${i}_{0 , lower} = 0.3 \cdot 0.5 {FC}_{R , i} \sqrt{\frac{π FvD}{Rt}}$ ${i}_{0 , upper} = 10 \cdot 0.5 {FC}_{R , i} \sqrt{\frac{π FvD}{Rt}}$ Default setting, see specific mechanisms below if noted |
| EᵣCᵣ mechanism | | |
| K_{O/A} | 10^{0.5}~10^{3 a} | |
| k_{f} | k_{f,lower}~k_{f,upper} _{^{a}} | ${k}_{f , lower} = {10}^{- 2} \cdot \frac{F}{RT} \cdot \frac{{vK}_{O / A}}{{K}_{O / A} + 1}$ |
| | | ${k}_{f , upper} = {10}^{4.5} \cdot \frac{F}{RT} \cdot \frac{{vK}_{O / A}}{{K}_{O / A} + 1}$ |
| Eₛₜₐᵣₜ | E_{window,c}~−0.2 −0.059log₁₀K_{O/A} V vs. NHE ^{b} | |
| CᵣEᵣ mechanism | | |
| K_{R/A} | 10⁻³~10^{-0.5 a} | |
| k_{f} | k_{f,lower}~k_{f,upper} _{^{a}} | ${k}_{f , lower} = {10}^{- 2} \cdot \frac{F}{RT} \cdot \frac{{vK}_{R / A}}{{K}_{R / A} + 1}$ |
| | | ${k}_{f , upper} = {10}^{4.5} \cdot \frac{F}{RT} \cdot \frac{{vK}_{R / A}}{{K}_{R / A} + 1}$ |
| E_{window,a} | 0.5 + 0.059log₁₀K_{R/A}~1.0 + 0.059log₁₀K_{R/A} vs. NHE ^{b} | |
| Eₛₜₐᵣₜ | Ewindow,c~−0.2 + 0.059log₁₀ K_{R/A} V vs. NHE ^{b} | |
| ECE mechanism | | |
| k | k_{lower}~kᵤₚₚₑᵣ _{^{a}} | ${k}_{upper} = {10}^{3} \frac{F}{RT} v$ |
| | | ${k}_{lower} = {10}^{- 1} \frac{F}{RT} v$ |
| E_{O2/R2} | −0.7~−0.1 V vs. NHE ^{b} | |
| i_{0,O2/R2} | i_{0,O2/R2,lower}~i_{0,02/R2,upper} _{^{a}} | ${i}_{0 , O 2 / R 2 , upper} = 10 \cdot 0.5 {FC}_{R , i} \sqrt{\frac{π FvD}{RT}}$ |
| | | ${i}_{0 , O 2 / R 2 , lower} = 0.3 \cdot 0.5 {FC}_{R , i} \sqrt{\frac{π FvD}{RT}}$ |
| Eₛₜₐᵣₜ | E_{window,c}~−0.6 vs. NHE ^{b} | |
| DISP mechanism | | |
| k | k_{lower}~k^{upper a} | ${k}_{upper} = {10}^{3} \frac{F}{RT} v$ |
| | | ${k}_{lower} = {10}^{- 1} \frac{F}{RT} v$ |
| Eₛₜₐᵣₜ | E_{window,c}~−0.6 vs. NHE ^{b} | |
| k_{DISP} | k_{DISP,ower}~k_{DISP,upper} ^{a} | ${k}_{DISP , upper} = {10}^{2} \frac{{k}^{3 / 2}}{{C}_{R , i}} \sqrt{\frac{RT}{Fv}}$ |
| | | ${k}_{DISP , upper} = {10}^{- 2} \frac{{k}^{3 / 2}}{{C}_{R , i}} \sqrt{\frac{RT}{Fv}}$ |

^{a} Variable values are randomly sampled logarithmically
^{b} Variable values are randomly sampled linearly.

### DOCTRINE OF EQUIVALENTS

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to +0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A method of analyzing an electrochemistry system comprising,
obtaining at least one cyclic voltammogram from an electrochemistry system;
generating a dataset from the at least one cyclic voltammogram;
evaluating the dataset using a machine learning model in a virtual space; and
when the evaluated dataset satisfies at least one criterion by the machine learning model, determining a probability of at least one electrochemical mechanism of the electrochemistry system.

2. The method of claim 1, wherein the dataset comprises numerical values of current, current density, scan rate, and any combinations thereof.

3. The method of claim 1, wherein the electrochemical mechanism is selected from the group consisting of a charge transfer, an interfacial charge transfer, an electron transfer, a chemical reaction, a solution reaction, a diffusion reaction, a single reversible electron transfers (Eᵣ), a Eᵣ step followed by reversible C steps (EᵣCᵣ), a Eᵣ step preceded by Cᵣ step (CᵣEᵣ), a systems of two Eᵣ steps connected by an irreversible rate-limiting C step with the second Eᵣ step being more thermodynamically facile than the first one (ECE), a two-electron transfer wherein the second Eᵣ step is replaced by a solution disproportionation reaction (DISP1), and any combinations thereof.

4. The method of claim 1, wherein at least one probability of an electrochemical mechanism of the electrochemistry system is determined to at least 95% accuracy.

5. The method of claim 1, further comprising determining a plurality of electrochemical mechanisms and ranking the plurality of electrochemical mechanisms of the electrochemistry system.

6. The method of claim 1, further comprising determining stoichiometric homogenous electrochemical mechanisms selected from the group consisting of: Eᵣ, EᵣCᵣ, CᵣEᵣ, ECE, and DISP1.

7. The method of claim 1, wherein the electrochemistry system is a portion of a system selected from the group consisting of: a catalyst, a fuel cell, a battery, a redox flow battery.

8. The method of claim 7, wherein the catalyst catalyzes a process selected from the group consisting of: a carbon dioxide reduction process, a carbon fixation process, a carbon sequestration process, a water electrolysis process, a hydrogen production process, and an energy storage process.

9. A method of training a machine model for analyzing an electrochemistry system comprising,
generating at least one dataset for at least one electrochemical mechanism comprising a set of parameters based on a definition of the at least one electrochemical mechanism; and
providing the at least one dataset as input training data to a machine learning model and training the machine learning model using the at least one dataset.

10. The method of claim 9, wherein the at least one dataset is generated via simulation.

11. The method of claim 9, further comprising adding Gaussian-type noise to the at least one dataset.

12. The method of claim 9, wherein the at least one dataset comprises numerical values of current, current density, scan rate, and any combinations thereof.

13. The method of claim 9, wherein the electrochemical mechanism is selected from the group consisting of a charge transfer, an interfacial charge transfer, an electron transfer, a chemical reaction, a solution reaction, a diffusion reaction, a single reversible electron transfers (Eᵣ), a Eᵣ step followed by reversible C steps (EᵣCᵣ), a Eᵣ step preceded by Cᵣ step (CᵣEᵣ), a systems of two Eᵣ steps connected by an irreversible rate-limiting C step with the second Eᵣ step being more thermodynamically facile than the first one (ECE), a two-electron transfer wherein the second Eᵣ step is replaced by a solution disproportionation reaction (DISP1), and any combinations thereof.

14. The method of claim 13, wherein the set of parameters is selected from the group consisting of: numbers of scan rate, values of scan rate, electrode double layer capacitance, standard rate constant of interfacial charge transfer in a concentration-dependent Butler-Volmer equation following Nicholson's formalism in the Eᵣ step, equilibrium constants and forward/backward rate constants in the Cᵣ step based on Savéant's definitions, and any combinations thereof.
